(19) United States
(12) Patent Application Publication
(10) Pub. No.: US 2026/0215292 A1
(43) Pub. Date: Jul. 23, 2026

(54) ELECTRONIC DEVICE WITH SPLIT LEAD

(71) Applicant: Texas Instruments Incorporated, Dallas, TX (US)

(72) Inventors: Yien Sien Khoo, ALOR GAJAH (MY); Lance Wright, Allen, TX (US); Huay Yann Tay, MELAKA (MY)

(21) Appl. No.: 19/032,765

(22) Filed: Jan. 21, 2025

(51) Int. Cl. H10W 70/40; H10W 70/04; H10W 74/10; H10W 90/00

(52) U.S. Cl. CPC H10W 70/421; H10W 70/048; H10W 74/111; H10W 90/756

(57) ABSTRACT

An electronic device includes a first lead extending outward from a first side of a package structure, and a second lead extending outward from a second side of the package structure. The first lead has an indent corresponding to a position of the second lead along a second direction that is orthogonal to the first direction. A lead frame has unit areas in rows along a first direction and columns along an orthogonal second direction and individually including prospective first and second leads, the first lead having first and second portions extending outward along the first direction from a third portion and spaced along the second direction, and the second lead extending along the first direction between the first and second portions of the first lead of an adjacent unit area and to the third portion of the first lead of the adjacent unit area.

### BACKGROUND

Small outline (SO) electronic devices often have dual row configurations with surface mount compatible leads on two opposite sides, including a large exposed thermal pad on one side for heat dissipation and mechanical rigidity. For example, SOT-223 devices can have a large thermal pad lead on one side and a three further leads on the opposite second side for regulator or transistor components. Other examples can include additional leads on the second side. The small outline surface mount package configurations provide good reliability for a variety of applications, such as industrial, automotive and other electrical systems. However, electronic device cost is important and reducing manufacturing cost and time can reduce the final unit price for small outline electronic devices.

### SUMMARY

In one aspect, an electronic device includes first and second leads with the first lead extending outward from a first side of a package structure and the second lead extending outward from an opposite second side of the package structure along a first direction. The first lead has an indent corresponding to the position of the second lead along an orthogonal second direction.

In another aspect, a system includes a circuit board having first and second conductive pads and an electronic device that comprises first and second leads. The first lead extends outward from a first side of a package structure and is coupled to the first conductive pad of the circuit board, The second lead is coupled to the second conductive pad of the circuit board and extends outward from an orthogonal side of the package structure, and the first lead has an indent corresponding to a position of the second lead along a second direction that is orthogonal to the first direction.

In a further aspect, a lead frame includes unit areas arranged in rows along a first direction and columns along an orthogonal second direction, where the respective unit areas include prospective first and second leads. The prospective first lead of each unit area has first and second portions extending outward along the first direction from a third portion and spaced apart from one another along the second direction, and the prospective second lead extending along the first direction between the first and second portions of the first lead of an adjacent unit area and to the third portion of the first lead of the adjacent unit area.

In another aspect, a method of fabricating an electronic device includes attaching a semiconductor die to a unit area of a lead frame, electrically coupling the semiconductor die to prospective first and second leads of the unit area of the lead frame, forming a package structure that encloses the semiconductor die and portions of the prospective first and second leads of the unit area of the lead frame, and trimming the lead frame to separate the prospective second lead of the unit area from a prospective first lead of a first adjacent unit area of the lead frame, and to separate the prospective first lead of the unit area from a prospective second lead of a second adjacent unit area of the lead frame with the prospective second lead of the second adjacent unit area spaced apart from and extending between first and second portions of the prospective first lead of the unit area.

### BRIEF DESCRIPTION OF THE DRAWINGS

FIG. 1 is a partial top system view of an electronic device with a split pad mounted on a circuit board.

FIG. 1A is a partial sectional side elevation view of the electronic device taken along line 1A-1A in FIGS. 1 and 1B.

FIG. 1B is a top plan view of the electronic device of FIGS. 1 and 1A.

FIG. 2 is a flow diagram of a method of fabricating an electronic device.

FIGS. 3 and 3A are partial top plan views of a lead frame with an array of SOT-223 unit areas arranged in rows and columns with interdigitated overlapping unit areas along a row direction.

FIGS. 4-8 are partial side elevation and top plan views of the electronic device of FIG. 1 undergoing fabrication processing according to an implementation of the method of FIG. 2 using the lead frame of FIGS. 3 and 3A.

FIG. 9 is a top plan view of another electronic device with an indented thermal pad.

### DETAILED DESCRIPTION

In the drawings, like reference numerals refer to like elements throughout, and the various features are not necessarily drawn to scale. Also, the term "couple" or "couples" includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. The example structures include layers or materials described as over or on another layer or material, which can be a layer or material directly on and contacting the other layer or material where other materials, such as impurities or artifacts or remnant materials from fabrication processing may be present between the layer or material and the other layer or material.

Unless otherwise stated, “about,” “approximately,” or “substantially” preceding a value means +/- 10 percent of the stated value. One or more structures, features, aspects, components, etc., may be referred to herein as first, second, third, etc., such as first and second terminals, etc., for ease of description in connection with a particular drawing, where such are not to be construed as limiting with respect to the claims. Various disclosed structures and methods of the present disclosure may be beneficially applied to manufacturing an electronic device such as an integrated circuit. While such examples may be expected to provide various improvements, no particular result is a requirement of the present disclosure unless explicitly recited in a particular claim.

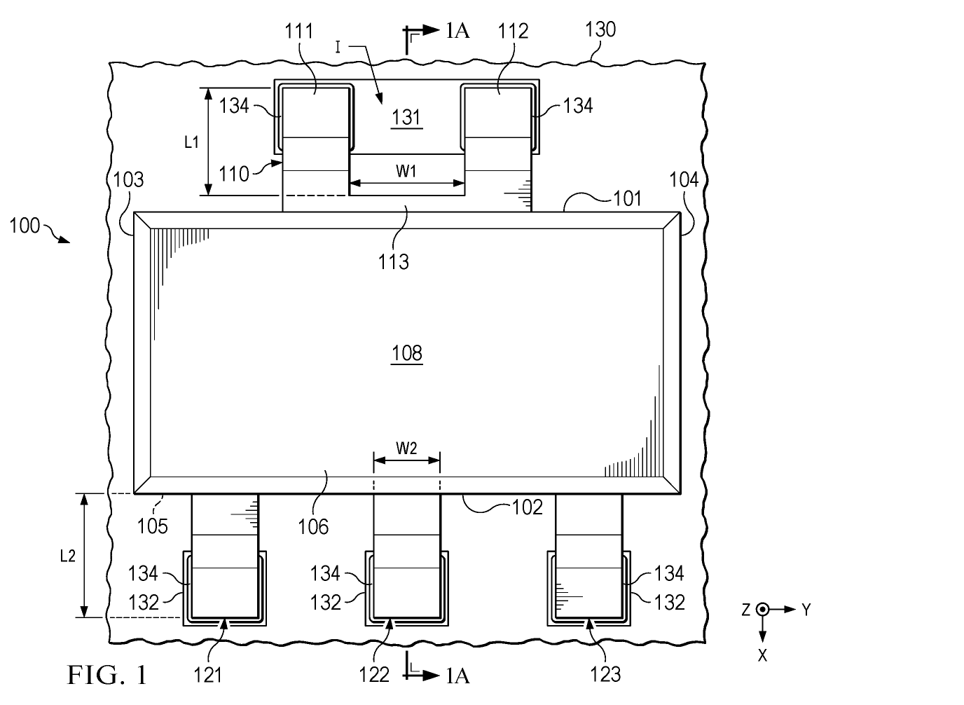

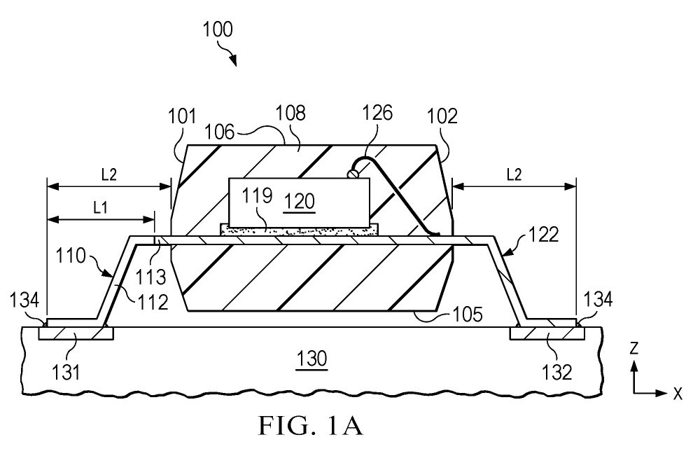

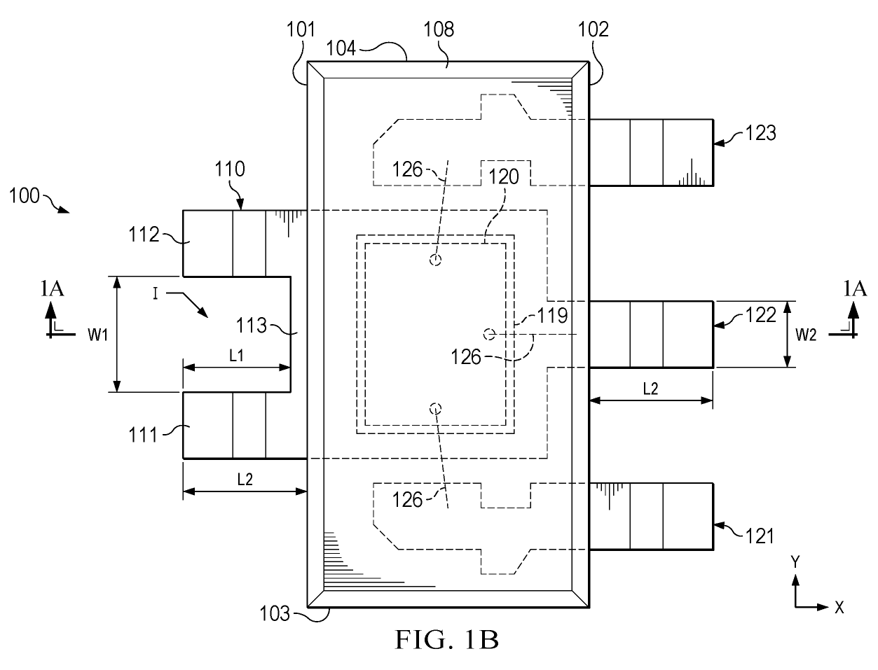

FIGS. 1-1B show a compact electronic device 100 with a split first lead 110 (e.g., a split thermal pad). FIG. 1 illustrates a partial top view of the electronic device 100 with a split pad mounted on a system circuit board. FIG. 1A shows a sectional side view of the electronic device 100 taken along line 1A-1A in FIGS. 1 and 1B, and FIG. 1B shows a top view of the electronic device 100 including dashed-line die, bond wires and internal lead structures.

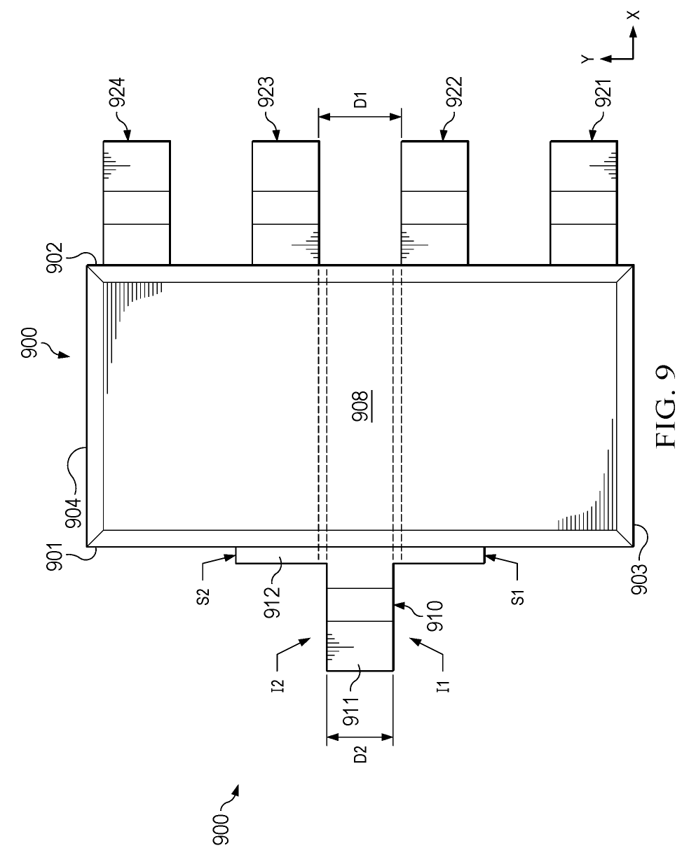

The first lead 110 has a concave split indented form with an indent “I” (FIGS. 1 and 1B) providing a space between first and second portions 111 and 112. The indent I facilitates lead frame strip unit area overlap by interleaving or interdigitation to increase strip density (e.g., more units per strip (UPS)) and lower lead frame cost per unit during manufacturing. The first and second portions 111 and 112 of the first lead 110 are formed to allow soldering to a surface mount pad 131 of a circuit board 130 (FIG. 1) and provide equivalent solderability, reliability and thermal performance compared to non-indented thermal pads with the added benefit of lower manufacturing cost. The example electronic device 100 is a small outline transistor package (e.g., an SOT-223 package) with four leads. Other split or indented lead implementations are possible with this or other small outline package types and forms and different numbers of leads (e.g., FIG. 9 below) having one or more indents.

FIGS. 1-1B show the electronic device 100 positioned in an example three-dimensional space with a first direction X, a perpendicular (orthogonal) second direction Y (FIGS. 1 and 1B), and a third direction Z (FIGS. 1 and 1A) that is perpendicular (orthogonal) to the respective first and second directions X and Y. Structures or features along any two of these directions are orthogonal to one another. The electronic device 100 has a molded package structure 108 with laterally opposite first and second sides 101 and 102, respectively, that are spaced apart from one another along the first direction X. The package structure 108 also has respective third and fourth sides 103 and 104 (e.g., longitudinal ends in FIGS. 1 and 1B) that are spaced apart from one another along the second direction Y, and respective fifth and sixth sides 105 and 106 (e.g., bottom and top sides in FIGS. 1 and 1A) that are spaced apart from one another along the third direction Z in the illustrated position.

The first lead 110 has a third portion 113 that is partially enclosed by the package structure 108 and extends outward along the first direction X from the first side 101 of the package structure 108. The respective first and second portions 111 and 112 of the first lead 110 are formed into gull wing shapes that extend outward from the third portion 113 and downward to form feet with approximately planar bottom sides configured for soldering to a circuit board and/or engagement with a socket of a host circuit board. In the illustrated example, the indent I creates a space between the first and second portions 111 and 112, and the first and second portions 111 are spaced apart from one another by a first width W1 along the second direction Y (FIGS. 1 and 1B).

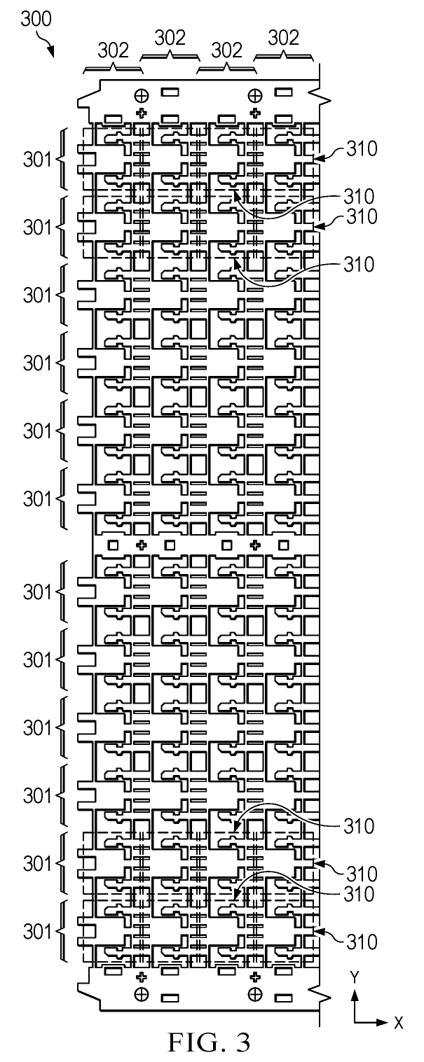

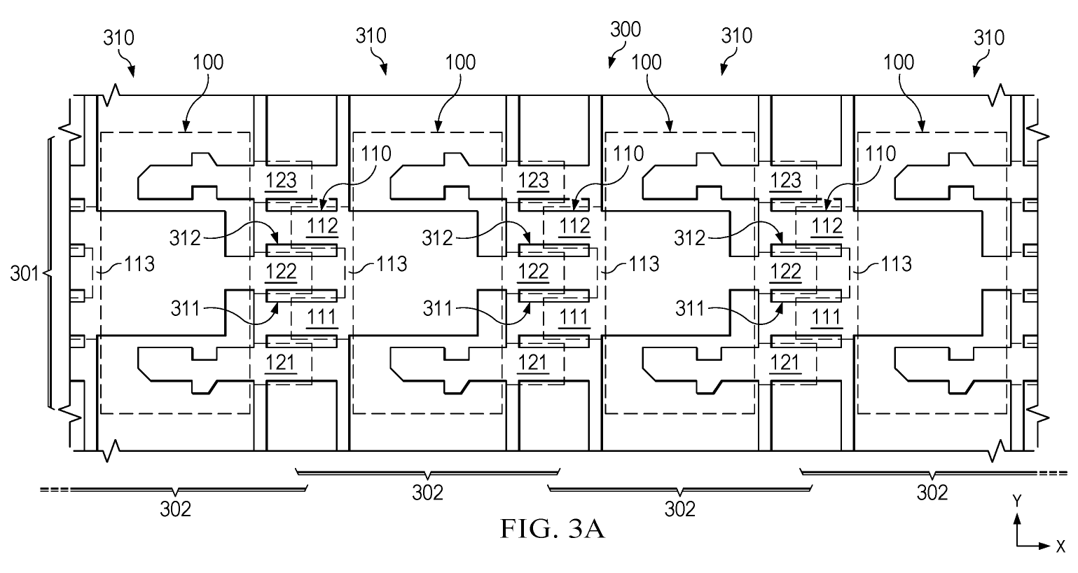

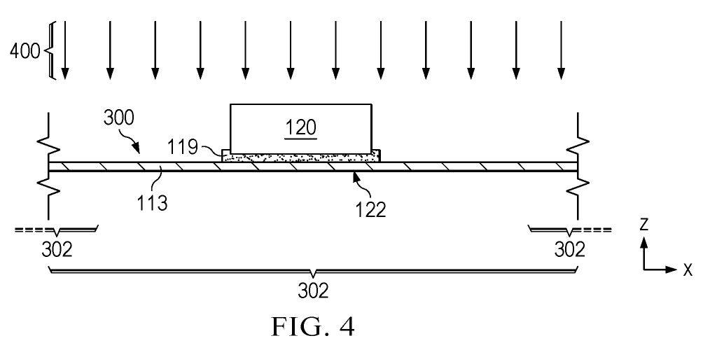

The indent I of the first lead 110 corresponds to a position of a second lead 122 along the second direction Y. In this example, a portion of the space between the portions 111 and 112 of the first lead 110 is occupied by a portion of a second lead of an adjacent unit area of the lead frame panel array during manufacturing (e.g., referred to as interdigitated or interleaved arrangement of a lead frame). Interleaving or overlapping of adjacent unit areas (e.g., along the first direction X in the illustrated example) advantageously increases the unit density of a given lead frame strip size. FIGS. 3 and 3A below illustrate one example of such an interdigitated lead frame (IDL) for the illustrated SOT-223, where the indent feature I of the first lead 110 facilitates interdigitating the lead frame. As further illustrated in FIG. 9 below, different designs can include one or more different indent features of the lead of a final device which accommodate or facilitate interdigitating to enhance the device density, for example, in terms of units per strip (UPS) to reduce manufacturing cost.

As further shown in FIGS. 1A and 1B, the example electronic device 100 includes a semiconductor die 120 attached to an interior portion of the first and second leads 110, 122 by die attach adhesive 119 or other suitable attachment materials (e.g., solder, etc.). As shown in FIGS. 1 and 1B, the example SOT-223 electronic device 100 has further leads 121, 122, and 123 that extend outward from the second side 102 of the package structure 108 along the first direction X. The leads 121-123 are formed into gull wing shapes that extend outward and downward to form respective feet with approximately planar bottom sides configured for soldering to a circuit board and/or engagement with a socket of a host circuit board. The third lead 121 in this example extends outward along the first direction X from the second side 102 of the package structure 108 and is spaced apart from (e.g., below in the view of FIG. 1B) the second lead 122 along the second direction Y. The fourth lead 123 extends outward along the first direction X from the second side 102 of the package structure 108 and the fourth lead 123 is spaced apart from (e.g., above) the second lead 122 along the second direction Y.

As further shown in FIG. 1B, the leads 110, 121-123 each have interior portions that are enclosed by the package structure 108, as well as exterior portions that extend outside the package structure 108. The external portion of the second lead 122 has a second width W2 along the second direction Y (FIGS. 1 and 1B), and the second width W2 is less than the first width W1. During manufacturing, the starting lead frame panel array undergoes trimming and forming operations to separate metal features (e.g., leads, die attach pads, etc.) of adjacent unit areas along a row direction (e.g., along the first direction X in the illustrated example), and the second lead 122 of an adjacent unit area is separated from all or portions of the first lead 110 as described further below. In this example, moreover, the first lead 110 and the second lead 122 are electrically connected to one another and form a contiguous metal structure that extends inside the package structure 108 between the first and second sides 101 and 102. In other examples, the first and second leads 110 and 122 need not be electrically or structurally connected to one another.

The semiconductor die 120 in one example includes one or more electronic components, such as a transistor having a source, drain, and gate terminals. The electronic device 100 in this example includes bond wires 126 forming respective electrical connections of conductive features (e.g., bond pads) of the semiconductor die 120 to interior portions of the respective leads 121-123, for example, to allow external connection to the transistor terminals of the semiconductor die 120. In other examples, different forms of electrical interconnections can be used, such as flip chip solder attachments, substrates, etc. (not shown), alone or in combination with one or more bond wires 126.

The indent I of the first lead 110 along the first side 101 in the illustrated example corresponds to the position along the second direction Y of the final second lead 122 of the second side 102. In this example, the second lead 122 is laterally aligned along the first direction X with the space between the first and second portions 111 and 112 of the first lead 110. The larger first width W1 of the first lead 110 corresponds to the trimming processing and/or initial lead frame panel feature design being large enough to accommodate the initial presence of the second lead of adjacent unit area that is ultimately separated from the final electronic device 100 during lead trimming operations.

In the illustrated example, the respective first and second portions 111 and 112 of the first lead 110 extend outward from the third portion 113 by a first length L1 along the first direction X. The second lead 122 extends outward from the second side 102 of the package structure 108 by a second length L2 along the first direction X, where the first length L1 is greater than half the second length L2. In this example, moreover, the first length L1 is less than the second length L2. The initial design of the lead frame panel array used during manufacturing, as well as the trimming and forming operations can be used to implement desired values for the first and second lengths L1 and L2 for a given finished electronic device 100 and also to facilitate increased device density (e.g., units per strip or UPS) to reduce manufacturing time and cost of the finished electronic device 100.

FIGS. 1 and 1A illustrate the electronic device 100 in a system installation, such as an automotive system, and industrial system, etc. The system in this example includes a circuit board 130 (e.g., a printed circuit board or PCB). The circuit board 130 has a top side with conductive metal pads 131 and 132. The electronic device 100 is mounted to or installed on the circuit board 130 in the illustrated example by solder 134 that forms electrical and mechanical connections of the first and second portions 111 and 112 of the first lead 110 to a first conductive metal pads 131 of the circuit board 130, as well as respective connections of the second, third, and fourth leads 122, 121, and 123 to respective ones of the conductive metal pads 132.

The illustrated installation is a surface mount solder attachment or mounting of the electronic device 100 on the circuit board 130. In another example, the electronic device 100 can be installed in a socket (not shown) with corresponding conductive metal terminals that engage the respective leads 110 and 121-123. The circuit board 130 in the illustrated example has a single conductive metal pad 131 having a width along the second direction Y that encompasses both the first and second portions 111 and 112 of the first lead 110. In another implementation, the circuit board 130 can have separate conductive metal pads (not shown) that individually correspond to the portions 111 and 112 of the first lead 110. The illustrated example advantageously allows installation of the example SOT-223 electronic device 100 on a circuit board 130 (or a socket, not shown) that is laid out or otherwise designed for conventional SOT-223 devices without requiring new circuit board layout (or new socket designs).

Other examples can include a lead with one or more indents that facilitate lead frame interdigitation during manufacturing to create other forms and types of packaged electronic devices, including without limitation small outline (SO) packages with one or more leads along two opposite sides (e.g., dual row surface mount configurations) having a wide variety of sizes and variations such as SOIC, SOT, and SOP (SSOP, TSSOP, VSSOP/MSOP, etc.). Various examples advantageously reduce manufacturing cost by enhanced device density and high lead frame area utilization with high reliability for different applications (e.g., automotive, industrial, etc.). In one example implementation for SOT-223 devices 100 having four leads, where a non-interdigitated implementation without lead indents provides 480 units per strip with a lead frame array strip dimensions 95 mm x 300 mm, and an interleaved implementation with the first lead 110 having the indent I in each interleaved unit area can provide 564-600 devices 100 per lead frame array strip having dimensions 95 mm x 300 mm (e.g., 108% to 25% improvement in units per strip (UPS)). Described examples and other implementations can have one or more pads exposed along the bottom side, although not a requirement of all possible examples.

The electronic device 100 of FIGS. 1-1B has a single indent I to form the first lead 110 into a split thermal pad to mimic two leads while allowing installation onto or in a circuit board 130 or socket configured for a conventional SOT-223 four-leaded part. The single indent split pad first lead 110 allows the second lead in the adjacent lead frame column to fit within (and possibly connect to) the split tab lead portions 111 and 112 prior to lead trimming operations. The split first lead 110 facilitates creation of an interdigitated SOT-223 lead frame 300 (e.g., FIGS. 3 and 3A below) with the lead frame columns closer together to improve the strip density and reduce unit cost and manufacturing time while maintaining suitable thermal performance, solderability and system reliability.

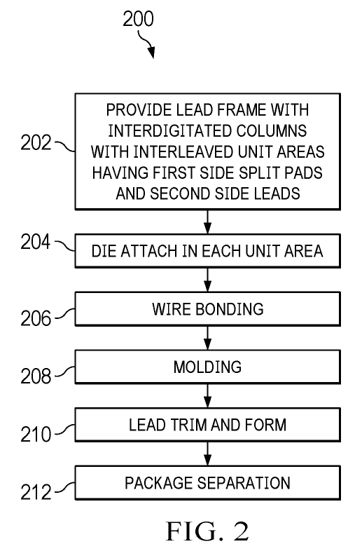

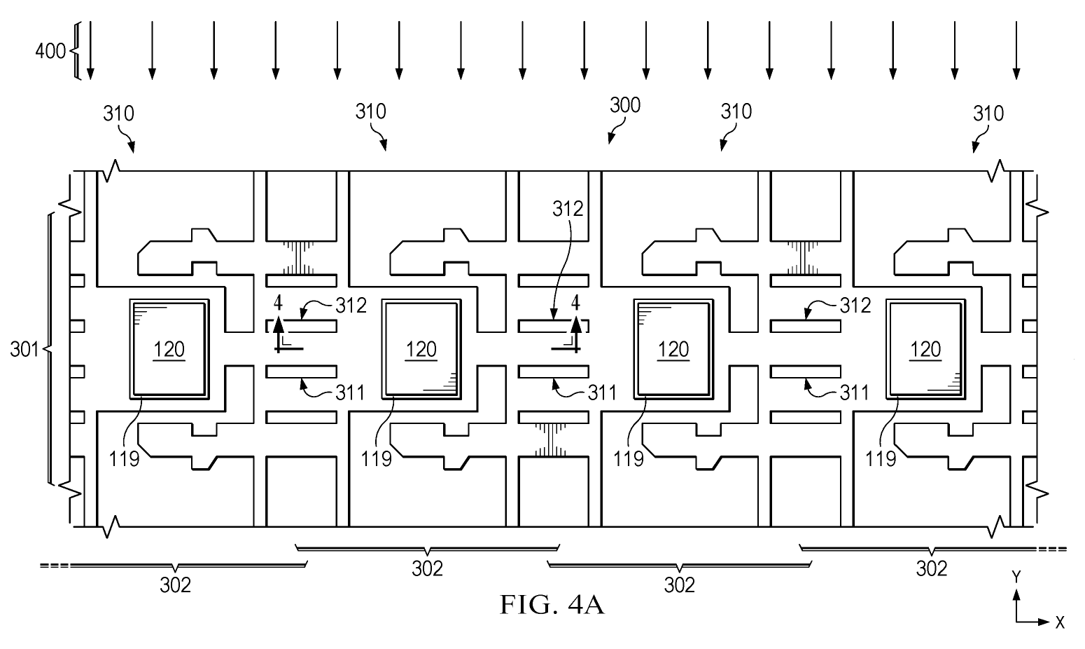

Referring now to FIGS. 2-8, FIG. 2 shows an example method 200 of fabricating an electronic device using an interdigitated lead frame, FIGS. 3 and 3A show an example interdigitated lead frame 300 with an array of SOT-223 DCQ unit areas 310, and FIGS. 4-8 show the example SOT-223 DCQ electronic device 100 undergoing fabrication processing according to an implementation of the method 200 of FIG. 2 using the interdigitated lead frame 300 of FIGS. 3 and 3A.

The method 200 begins at 202 in FIG. 2 with providing a lead frame with interdigitated unit areas having interleaved unit areas. FIGS. 3 and 3A show respective partial top views of an interdigitated lead frame panel array 300. Any suitable arrangement of unit areas 310 can be used. The example lead frame 300 has an array of SOT-223 unit areas 310 arranged in rows 301 along the first direction X and columns 302 along the second direction Y with interdigitated overlapping unit areas along the row direction X. At least some of the individual unit areas 310 have first side split pad portions and second side leads.

FIG. 3A shows dashed-line profiles of the ultimately formed and separated electronic devices 100 for visual reference along one example row 301 of the lead frame 300. As shown in FIG. 3A, the individual unit areas 310 of the lead frame 300 have a prospective wide, split (indented) first lead 110 and a prospective second lead 122, as well as the prospective third and fourth leads 121 and 123. The prospective first lead 110 of each unit area 310 has first and second portions 111 and 112 that extend outward along the first direction X from a corresponding third portion 113, with the prospective first and second portions 111 and 112 spaced apart from one another along the second direction Y. In the illustrated example, the prospective second lead 122 of each unit area 310 extends along the first direction X between the first and second portions 111 and 112 of the first lead 110 of an adjacent unit area 310 and the prospective second lead 122 extends to the third portion 113 of the first lead 110 of the adjacent unit area 310. In this example, moreover, the prospective first and second leads 110 and 122 of each unit area 310 are contiguous with one another, although not a requirement of all possible implementations.

The lead frame 300 in one example starts as a single contiguous metal structure, such as copper, aluminum, etc. of uniform thickness (e.g., along the orthogonal third direction into the page in FIGS. 3 and 3A) with the illustrated structural features formed by punching, etching or other suitable technique. In other implementations, the lead frame can include raised or recessed features in one or more of the unit areas 310 and/or in peripheral side portions thereof, which can be created by half etching, grinding, bending using suitable tooling (not shown), etc.

The illustrated lead frame 300 includes a first opening 311 (e.g., a slot) in each unit area 310 that extends along the first direction X between portions of the prospective second lead 122 of that unit area 310 and an upper portion of the prospective first portion 111 of the first lead 110 of an adjacent unit area 310. This example also includes a second opening 312 (e.g., a second slot) in each unit area 310 that extends along the first direction X between portions of the prospective second lead 122 of that unit area 310 and a lower portion of the prospective second portion 112 of the first lead 110 of the adjacent unit area 310. The openings 311 and 312 in this example facilitate subsequent lead frame trimming operations, for example, to allow a single rectangular punch die feature to separate the end of the second lead 122 of one unit area 310 from the third portion 113 of the adjacent unit area 310. This configuration also allows a single rectangular punch die feature to separate the end of the first portion 111 of the first lead 110 of one unit area 310 from the lead frame 300, and another single rectangular punch die feature to separate the end of the second portion 112 of the first lead 110 from the lead frame 300.

In another example, the openings 311 and 312 can be omitted, and a U-shaped punch die feature can be used to separate the end of the second lead 122 of one unit area 310 from the third portion 113 of the first lead 110 of the adjacent unit area 310 and to concurrently separate the upper and lower sides of the second lead 122 from the sides of the first and second portions 111 and 112 of the first lead 110 of the adjacent unit area 310. Other lead frame designs are possible to accommodate the indented feature or features of a first lead for inter-digitized arrangements of adjacent unit areas.

Returning to FIG. 2, the method 200 includes die attach processing at 204 in each unit area 310 of the lead frame 300. FIGS. 4 and 4A show respective partial side and top views of one example, in which a die attach process 400 is performed that attaches an instance of the semiconductor die 120 to the individual unit areas 310 of the lead frame 300. In one example, the die attach process 400 includes forming conductive or non-conductive die attach adhesive 119 in select portions of each unit area 310 of the lead frame 300, for example, by dispensing, printing, silk screening or other suitable technique, followed by attaching an instance of the semiconductor die 122 the previously formed die attach adhesive 119 in each unit area 310, for example, using automated pick and place equipment (not shown). In one implementation, the die attach process 400 can further include subsequent adhesive curing processing to cure the die attach adhesive 119, such as by thermal heating, UV exposure or other suitable technique.

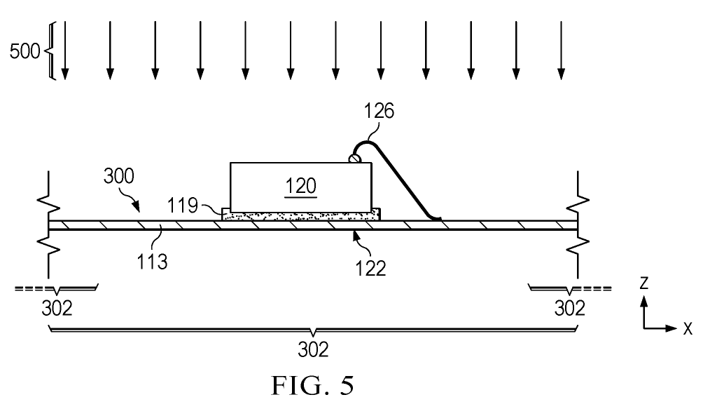

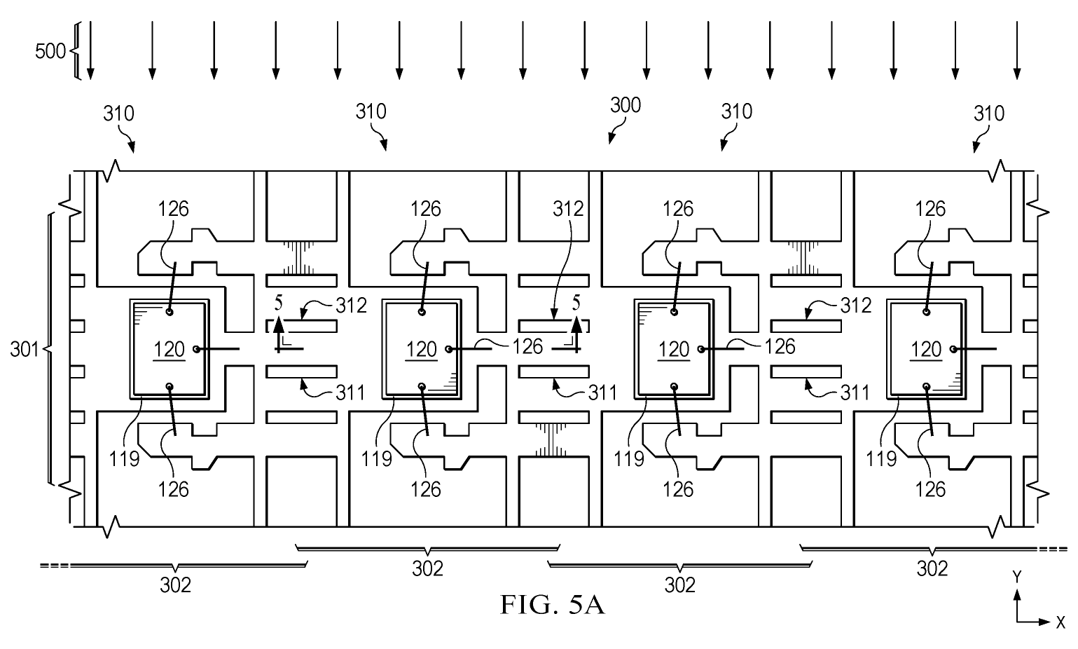

The method 200 continues at 206 in FIG. 2 with electrical coupling to couple the conductive terminals of the semiconductor die 122 the prospective leads in each unit area 310 of the lead frame 300. FIGS. 5 and 5A show respective partial side and top views of one example, in which a wirebonding process 500 is performed that electrically couples the semiconductor die 120 to the prospective first and second leads 110 and 122 of the unit area 310 of the lead frame 300, in addition to coupling corresponding terminals of each semiconductor die 120 to the example 3^{rd} and fourth leads 121 and 123 in each unit area 310. The illustrated process 500 forms a bond wire 126 between the semiconductor die 120 and one of the prospective first and second leads 110 and 122 of the unit area 310 of the lead frame 300 since these are structurally coupled to one another. In another implementation, where the first and second leads 110 and 122 are not to be electrically connected to one another in the finished electronic device 100, separate bond wires 126 can be formed to connect the first and second leads 110 and 122 to respective conductive terminals (e.g., bond pads) of the semiconductor die 120 in each unit area 310. The wirebonding process 500 also forms additional bond wires 126 that connect corresponding conductive terminals or features of the semiconductor die 120 to the third and fourth leads 121 and 123 in the illustrated example. In other implementations, other types and forms of electrical connection processing can be performed, for example, using conductive metal clips, flip-chip electrical interconnections (not shown) alone or in combination with wire bonding.

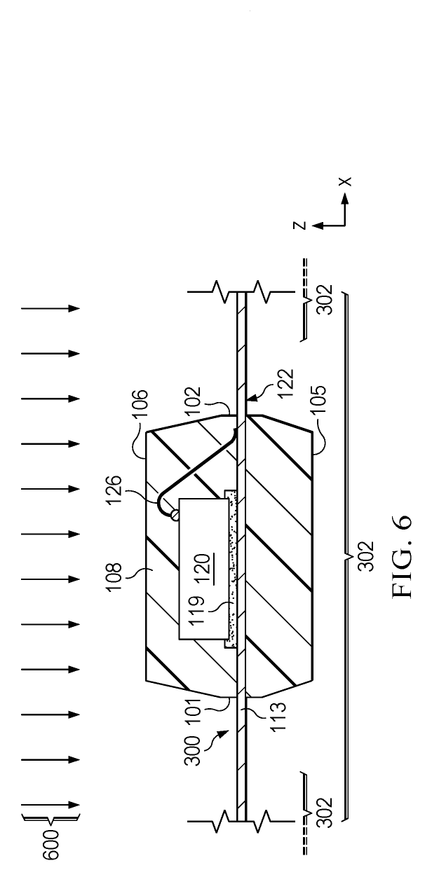

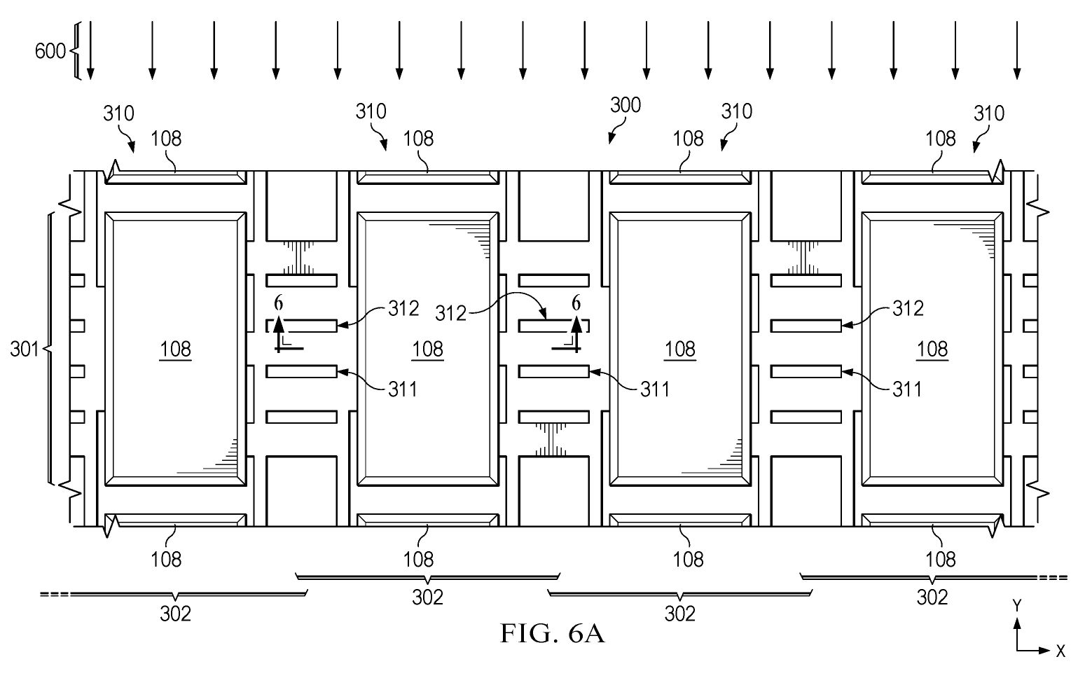

The method 200 continues at 208 in FIG. 2 with molding processing to form the molded package structure 108. FIGS. 6 and 6A show respective partial side and top views of one example, in which a molding process 600 is performed to form the molded package structure 108 that encloses the bond wires 126, the semiconductor die 120 and interior portions of the prospective leads 110 and 121-123 in each unit area 310 of the lead frame. In one example, a single mold cavity can be used to form a unitary magnetic molded structure 108 that extends across all the rows and columns of the lead frame panel array structure. In the illustrated implementation, individual mold cavities are used to form respective molded magnetic package structures 108 in each unit area, for example, to facilitate lead trimming and forming operations. In another example, individual mold cavities extend across two or more unit areas of the lead frame panel array structure, for example, to form package structures 108 along rows or columns of the array structure.

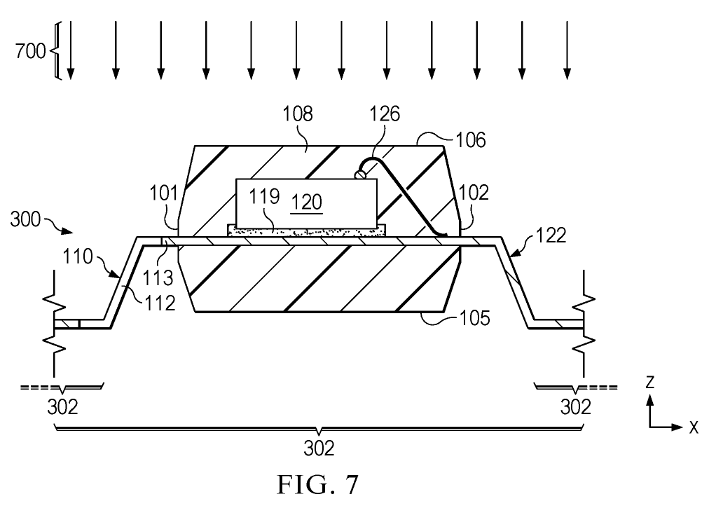

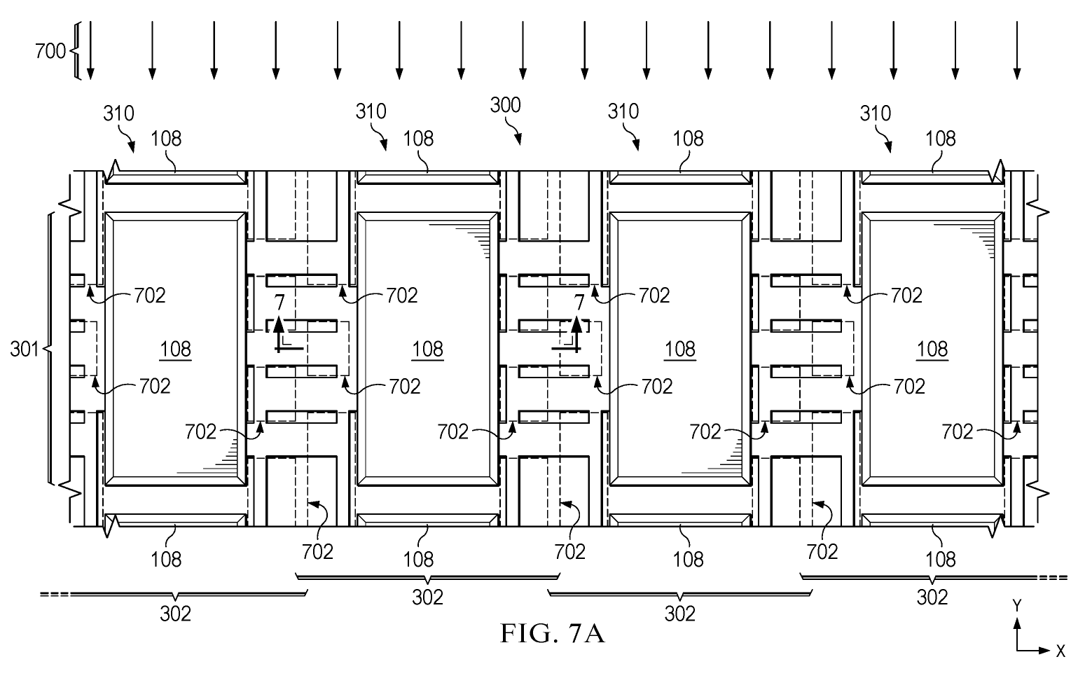

At 210 in FIG. 2, the method 200 includes trimming and forming operations. FIGS. 7 and 7A show respective partial side and top views of one example, in which a lead trimming process 700 is performed that separates the prospective second lead 122 of the individual unit areas 310 from a prospective first lead 110 of a first adjacent unit area 310 of the lead frame 300. In addition, the trimming process 700 separates the prospective first lead 110 of the unit area 310 from a prospective second lead 122 of a second adjacent unit area 310 of the lead frame 300 with the prospective second lead 122 of the second adjacent unit area 310 spaced apart from and extending between first and second portions 111 and 112 of the prospective first lead 110 of the unit area 310. In the illustrated example, the trimming process 700 also separates the third portion 113 of the prospective first lead 110 that is connected to the first and second portions 111 and 112 of the prospective first lead 110 of the unit area 310 from the prospective second lead 122 of the second adjacent unit area 310. In one example, the trimming process 700 uses punch die tooling (not shown) to punch through the example areas 702 in each unit area 310.

The lead trimming and forming at 210 in FIG. 2 also includes forming the prospective first and second leads 110 and 121-123 of the unit area 310 to extend below a bottom side 105 of the package structure 108. The process 700 in FIG. 7 illustrates lead forming using suitable tooling (not shown) to form the leads 110 and 121-123 into the gullwing lead structures, for example, as illustrated and described above in connection with FIGS. 1-1B. The method 200 in one example can include optional plating (not shown) of the leads in each unit area 310 of the lead frame 300 after molding at 208, which can be before, after or between lead trimming and forming at 210 in FIG. 2.

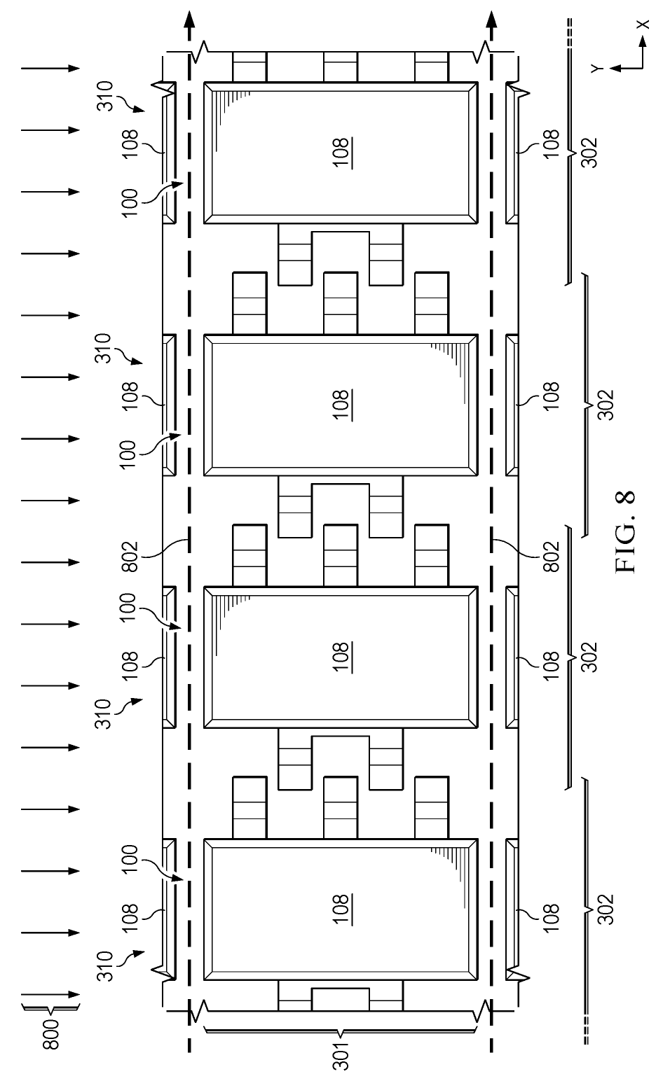

The method 200 continues at 212 in one example with further package separation processing separating 212 a semiconductor device 100 of the unit area 310 from the lead frame 300. FIG. 8 shows one example, in which a package separation process 800 is performed that separates adjacent packaged electronic devices from one another along columns of the starting lead frame panel array structure 300 to provide separated packaged electronic devices 100 as described above in connection with FIGS. 1-1B. In one example, the package separation process 800 includes saw cutting to separate remaining portions of the lead frame 300 (e.g., tie bars) from the electronic devices 100 in each unit area 310 along cut lines 802.

FIG. 9 shows another electronic device 900, such as a SOT-233 NDC device with five leads, including a first lead 910 along a first side 901 and further leads 921-924 along an opposite second side 902, including a second lead 922, a third lead 923, a fourth lead 921, and a fifth lead 924. The device 900 has a semiconductor die (not shown) with electrical connections (e.g., bond wires, not shown) to the respective leads 910 and 921-924, with a package structure 908 (e.g., molding compound) having lateral sides 901-904. The first lead 910 in this example includes first and second indents I1 and I2 extending into a first portion 911, as well as a non-indented second portion 912 that extends into the package structure 908 along the first direction X. In one example, the indented first lead 910 is a thermal pad, and may be electrically connected to one of the other leads 921-924, although not a requirement of all possible implementations.

The first lead 910 extends outward from the first side 901 of the package structure 908 along the first direction X. The second lead 922 extends outward from the second side 902 of the package structure 908, and the first and second sides 901 and 902 of the package structure 908 are spaced apart from one another along the first direction X. The third lead 923 extends outward from the second side 902 of the package structure 908 and is spaced apart from the second lead 922 by a first distance D1 along the orthogonal second direction Y. The first lead 910 has opposite first and second sides S1 and S2, respectively, that are spaced apart from one another along the second direction Y. The first indent I1 extends into the first side S1 of the first lead 910 and corresponds to the position of the second lead 922 along the second direction Y, such that the indented portion of the first side S1 of the first lead 910 provides clearance to an instance of the second lead 922 of an adjacent unit area during fabrication in an interdigitated lead frame panel array. The second indent I2 extends into the second side S2 of the first lead 910 and corresponds to the position of the third lead 923 along the second direction Y such that the indented portion of the second side S2 of the first lead 910 provides clearance with respect to an instance of the third lead 923 of an adjacent unit area in a lead frame panel array. This structure facilitates providing a narrow first portion 911 of the indented first lead 910 having a distance D2 that is less than the first distance D1. The indented first lead 910 facilitates interdigitation of a lead frame panel array to facilitate high density manufacturing with reduced product cost and fabrication time with similar beneficial advantages as described above in connection with the electronic device 100 of FIGS. 1-1B.

Modifications are possible in the described examples, and other implementations are possible, within the scope of the claims.

What is claimed is:

1. An electronic device, comprising:
a first lead extending outward from a first side of a package structure; and
a second lead extending outward from a second side of the package structure, the first and second sides of the package structure spaced apart from one another along a first direction;
the first lead having an indent corresponding to a position of the second lead along a second direction that is orthogonal to the first direction.

2. The electronic device of claim 1, wherein:
the first lead has a first portion, a second portion, and a third portion, the first and second portions extending outward from the third portion and spaced apart from one another by a first width along the second direction; and
the second lead has a second width along the second direction, the second width less than the first width.

3. The electronic device of claim 2, wherein the second lead is laterally aligned with a space between the first and second portions of the first lead along the first direction.

4. The electronic device of claim 3, further comprising:
a third lead extending outward from the second side of the package structure and spaced apart from the second lead along the second direction; and
a fourth lead extending outward from the second side of the package structure and spaced apart from the second lead along the second direction.

5. The electronic device of claim 3, wherein the first and second leads are electrically connected to one another.

6. The electronic device of claim 2, wherein:
the first and second portions of the first lead extend outward from the third portion by a first length along the first direction;
the second lead extends outward from the second side of the package structure by a second length along the first direction; and
the first length is greater than half the second length.

7. The electronic device of claim 6, wherein the first length is less than the second length.

8. The electronic device of claim 2, wherein the first and second leads are electrically connected to one another.

9. The electronic device of claim 1, further comprising a third lead extending outward from the second side of the package structure and spaced apart from the second lead along the second direction, wherein:
the first lead has opposite first and second sides spaced apart from one another along the second direction;
the indent is a first indent extending into the first side of the first lead and corresponding to the position of the second lead along the second direction; and
the first lead has a second indent extending into the second side of the first lead and corresponding to a position of the third lead along the second direction.

10. A system, comprising:
a circuit board having first and second conductive pads; and
an electronic device, comprising:
a first lead extending outward from a first side of a package structure and coupled to the first conductive pad of the circuit board; and
a second lead coupled to the second conductive pad of the circuit board and extending outward from a second side of the package structure, the first and second sides of the package structure spaced apart from one another along a first direction;
the first lead having an indent corresponding to a position of the second lead along a second direction that is orthogonal to the first direction.

11. The system of claim 10, wherein:
the first lead has a first portion coupled to the first conductive pad of the circuit board, a second portion coupled to the first conductive pad of the circuit board, and a third portion, the first and second portions extending outward from the third portion and spaced apart from one another by a first width along the second direction;
the second lead has a second width along the second direction, the second width less than the first width; and
the second lead is laterally aligned with a space between the first and second portions of the first lead along the first direction.

12. The system of claim 11, wherein the first and second leads are electrically connected to one another.

13. The system of claim 11, wherein:
the first and second portions of the first lead extend outward from the third portion by a first length along the first direction;
the second lead extends outward from the second side of the package structure by a second length along the first direction; and
the first length is greater than half the second length.

14. The system of claim 10, wherein:
the electronic device further comprises a third lead extending outward from the second side of the package structure and spaced apart from the second lead along the second direction;
the first lead has opposite first and second sides spaced apart from one another along the second direction;
the indent is a first indent extending into the first side of the first lead and corresponding to the position of the second lead along the second direction; and
the first lead has a second indent extending into the second side of the first lead and corresponding to a position of the third lead along the second direction.

15. A lead frame, comprising unit areas arranged in rows along a first direction and columns along an orthogonal second direction, the respective unit areas including prospective first and second leads;
the prospective first lead of each unit area having first and second portions extending outward along the first direction from a third portion and spaced apart from one another along the second direction; and
the prospective second lead of each unit area extending along the first direction between the first and second portions of the first lead of an adjacent unit area and to the third portion of the first lead of the adjacent unit area.

16. The lead frame of claim 15, wherein the prospective first and second leads of each unit area are contiguous with one another.

17. The lead frame of claim 15, wherein each unit area includes:
a first opening between the prospective second lead of the unit area and the first portion of the prospective first lead of the adjacent unit area; and
a second opening between the prospective second lead of the unit area and the second portion of the prospective first lead of the adjacent unit area.

18. A method of fabricating an electronic device, the method comprising:
attaching a semiconductor die to a unit area of a lead frame;
electrically coupling the semiconductor die to prospective first and second leads of the unit area of the lead frame;
forming a package structure that encloses the semiconductor die and portions of the prospective first and second leads of the unit area of the lead frame; and
trimming the lead frame to separate the prospective second lead of the unit area from a prospective first lead of a first adjacent unit area of the lead frame, and to separate the prospective first lead of the unit area from a prospective second lead of a second adjacent unit area of the lead frame with the prospective second lead of the second adjacent unit area spaced apart from and extending between first and second portions of the prospective first lead of the unit area.

19. The method of claim 18, wherein trimming the lead frame comprises separating a third portion of the prospective first lead that is connected to the first and second portions of the prospective first lead of the unit area from the prospective second lead of the second adjacent unit area.

20. The method of claim 18, further comprising forming the prospective first and second leads of the unit area to extend below a bottom side of the package structure.

21. The method of claim 18, further comprising separating a semiconductor device of the unit area from the lead frame.

22. The method of claim 18, wherein electrically coupling the semiconductor die to the prospective first and second leads of the unit area of the lead frame includes forming a bond wire between the semiconductor die and one of the prospective first and second leads of the unit area of the lead frame.
